(19) United States
(12) Patent Application Publication
(10) Pub. No.: US 2026/0020243 A1
(43) Pub. Date: Jan. 15, 2026

(54) MEMORY DEVICE WITH INTER-LAYER DIELECTRIC REGIONS

(71) Applicant: SAMSUNG ELECTRONICS CO, LTD., Suwon-si (KR)

(72) Inventors: Hanmin NAM, Suwon-si (KR); Jeunghwan PARK, Suwon-si (KR)

(73) Assignee: SAMSUNG ELECTRONICS CO, LTD., Suwon-si (KR)

(21) Appl. No.: 19/027,426

(22) Filed: Jan. 17, 2025

(30) Foreign Application Priority Data
Jul. 11, 2024 (KR) 10-2024-0092014

(51) Int. Cl. H10B 43/40; G11C 16/04; H10B 41/20; H10B 41/35; H10B 41/41; H10B 43/20; H10B 43/35

(52) U.S. Cl. CPC H10B 43/40; G11C 16/0483; H10B 41/20; H10B 41/35; H10B 41/41; H10B 43/20; H10B 43/35

(57) ABSTRACT

A memory device includes a cell region in which a memory cell array is disposed, and a peripheral circuit region at least partially vertically overlapping the cell region. The peripheral circuit region includes a first sub-peripheral circuit region, and a second sub-peripheral circuit region at least partially vertically overlapping the first sub-peripheral circuit region. A thickness of a first lowermost inter-layer dielectric (ILD) region of the first sub-peripheral circuit region is different from a thickness of a second lowermost ILD region of the second sub-peripheral circuit region.

### CROSS-REFERENCE TO RELATED APPLICATIONS

This application claims benefit of priority under 35 U.S.C. § 119 to Korean Patent Application No. 10-2024-0092014, filed on Jul. 11, 2024, in the Korean Intellectual Property Office, the disclosure of which is incorporated by reference herein in its entirety.

### BACKGROUND

The present disclosure relates generally to a memory device, and more particularly, to a memory device with a three-dimensional (3D) structure.

Memory devices may be used to store data and/or may be classified into volatile memory devices and non-volatile memory devices. An example of a non-volatile memory device may include, but may not be limited to, a flash memory device and may be used in information and communication devices, such as, but not limited to, mobile phones, digital cameras, portable computer devices, stationary computer devices, or the like. Recently, as information and communication devices may have become more multifunctional, increased capacity and/or increased integration of memory devices may be demanded. To at least partially address the increased demand for increased capacity and/or integration, three-dimensional (3D) non-volatile memory devices may have been proposed. The 3D non-volatile memory devices may include a plurality of word lines that may be stacked on a substrate in a vertical direction.

As the number of word lines stacked on the substrate in the 3D non-volatile memory device increases, the area of a cell region needed to provide the same capacity may have decreased. However, the total area of a peripheral circuit region required to provide the same capacity may not significantly change. Accordingly, when viewed in a plan view, the percentage (or ratio) of area occupied by the peripheral circuit region in the 3D non-volatile memory device may have increased. As a result, space utilization of a memory device may be reduced and may also constrain the design of relatively highly integrated memory devices.

### SUMMARY

One or more example embodiments of the present disclosure provide a memory device including two or more overlapping peripheral circuit regions, wherein, when an input/output circuit and a row decoder circuit are formed in different peripheral circuit regions, the performance and degree of integration of each circuit are improved, when compared to related memory devices, by varying the thicknesses of lowermost inter-layer dielectric (ILD) regions of the two or more peripheral circuit regions.

According to an aspect of the present disclosure, a memory device includes a cell region in which a memory cell array is disposed, and a peripheral circuit region at least partially vertically overlapping the cell region. The peripheral circuit region includes a first sub-peripheral circuit region, and a second sub-peripheral circuit region at least partially vertically overlapping the first sub-peripheral circuit region. A thickness of a first lowermost inter-layer dielectric (ILD) region of the first sub-peripheral circuit region is different from a thickness of a second lowermost ILD region of the second sub-peripheral circuit region.

According to an aspect of the present disclosure, a memory device includes a plurality of chips including a first chip, a second chip, and a third chip. The plurality of chips are sequentially stacked. A memory cell array is disposed in the first chip. A second sub-peripheral circuit region is disposed in the second chip. A first sub-peripheral circuit region is disposed in the third chip. A thickness of a first lowermost ILD region of the first sub-peripheral circuit region is different from a thickness of a second lowermost ILD region of the second sub-peripheral circuit region.

According to an aspect of the present disclosure, a memory device includes a cell region in which a memory cell array is disposed, and a peripheral circuit region at least partially vertically overlapping the cell region. The peripheral circuit region includes a first sub-peripheral circuit region, and a second sub-peripheral circuit region at least partially vertically overlapping the first sub-peripheral circuit region. The first sub-peripheral circuit region includes a first transistor region and a second transistor region. The second sub-peripheral circuit region includes a third transistor region and a fourth transistor region. Thicknesses of first lowermost ILD regions of transistors disposed in the first transistor region and the second transistor region are different from thicknesses of second lowermost ILD regions of transistors disposed in the third transistor region and the fourth transistor region.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a block diagram of a memory device, according to an embodiment;

FIG. 2A is a diagram showing an example of one of memory blocks included in a memory cell array of FIG. 1 and a peripheral circuit corresponding to the memory block, according to an embodiment;

FIG. 2B is a diagram showing an example of a memory block according to a comparative example and a peripheral circuit corresponding to the memory block, according to an embodiment;

FIG. 3 is a diagram of an example of circuits arranged in sub-peripheral circuit regions, according to an embodiment;

FIG. 4 is a cross-sectional view showing an example of a memory device, according to an embodiment;

FIG. 5 is a cross-sectional view of structures of elements respectively arranged in a first sub-peripheral circuit region and a second sub-peripheral circuit region, according to an embodiment;

FIG. 6 is a cross-sectional view of structures of elements respectively arranged in a first sub-peripheral circuit region and a second sub-peripheral circuit region, according to an embodiment;

FIG. 7 is a cross-sectional view of structures of elements respectively arranged in a first sub-peripheral circuit region and a second sub-peripheral circuit region, according to an embodiment;

FIG. 8 is a cross-sectional view of structures of elements respectively arranged in a first sub-peripheral circuit region and a second sub-peripheral circuit region, according to an embodiment;

FIG. 9 is a cross-sectional view of structures of elements respectively arranged in a first sub-peripheral circuit region and a second sub-peripheral circuit region, according to an embodiment;

FIG. 10 is a cross-sectional view of structures of elements respectively arranged in a first sub-peripheral circuit region and a second sub-peripheral circuit region, according to a comparative example; and

FIG. 11 is a cross-sectional view showing an example of a memory device, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “CoSiₓ”, “TiSiₓ”, and the like may refer to a material made of elements included in each of the terms and is not a chemical formula representing a stoichiometric relationship.

Hereinafter, various embodiments of the present disclosure are described with reference to the accompanying drawings.

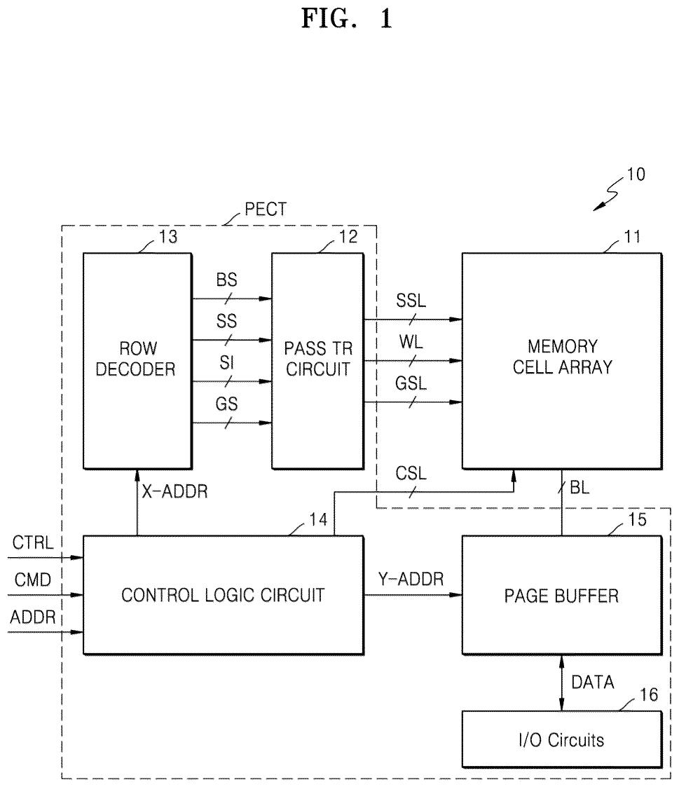

FIG. 1 is a block diagram of a memory device 10, according to an embodiment.

Referring to FIG. 1, the memory device 10 may include a memory cell array 11 and a peripheral circuit PECT. In one or more embodiments, the memory device 10 may be and/or may include a non-volatile memory device. As used herein, a memory device may refer to a non-volatile memory device.

The memory cell array 11 may be connected to a pass transistor circuit 12 through word lines WL, string selection lines SSL, and ground selection lines GSL, and may be connected to a page buffer 15 through bit lines BL. The memory cell array 11 may include a plurality of memory cells, and for example, the plurality of memory cells may be and/or may include flash memory cells. Hereinafter, for ease of description, embodiments described below may describe a case in which the plurality of memory cells are NAND flash memory cells as an example. However, the present disclosure is not limited thereto. In some embodiments, the plurality of memory cells may be and/or may include resistive memory cells, such as, but not limited to, resistive random-access memory (RAM) (ReRAM), phase change RAM (PRAM), magnetic RAM (MRAM), or the like.

In an embodiment, the memory cell array 11 may include a three-dimensional (3D) memory cell array. The 3D memory cell array may include a plurality of NAND strings, and each of the plurality of NAND strings may include memory cells that may be respectively connected to word lines that may be vertically stacked on a substrate. However, the present disclosure is not limited thereto. For example, in some embodiments, the memory cell array 11 may include a two-dimensional (2D) memory cell array, and the 2D memory cell array may include a plurality of NAND strings arranged in row and column directions.

The peripheral circuit PECT may be arranged adjacent to the memory cell array 11. For example, the peripheral circuit PECT may be arranged perpendicular to the memory cell array 11 to overlap the memory cell array 11 in a plan view. The peripheral circuit PECT may include the pass transistor (TR) circuit 12, a row decoder 13, a control logic circuit 14, the page buffer 15, and an input/output (I/O) circuit 16. In some embodiments, the peripheral circuit PECT may further include a voltage generator, a data I/O circuit, a temperature sensor, a command decoder, an address decoder, or the like.

The pass transistor circuit 12 may be connected to the row decoder 13 through block selection signal lines BS, string selection line driving signal lines SS, word line driving signal lines SI, and ground selection line driving signal lines GS. Hereinafter, the string selection line driving signal lines SS, the word line driving signal lines SI, and the ground selection line driving signal lines GS may be generally referred to as driving signal lines. The pass transistor circuit 12 may include a plurality of pass transistors, and the plurality of pass transistors may be controlled by block selection signals received through the block selection signal lines BS and may provide string selection line driving signals, word line driving signals, and ground selection line driving signals to the string selection lines SSL, the word lines WL, and the ground selection lines GSL, respectively.

The row decoder 13 may output, to the block selection signal lines BS, a block selection signal for selecting one of the plurality of memory blocks, in response to a row address X-ADDR. In addition, the row decoder 13 may, in response to the row address X-ADDR, output a word line driving signal for selecting one of the word lines WL of the selected memory block to the word line driving signal lines SI, output a string selection line driving signal for selecting one of the string selection lines SSL to the string selection line driving signal lines SS, and output a ground selection line driving signal for selecting one of the ground selection lines GSL to the ground selection line driving signal lines GS. In some embodiments, the word line driving signal line SI may be referred to as a global word line.

The page buffer 15 may select some of the bit lines BL in response to a column address Y-ADDR. In particular, the page buffer 15 may operate as a write driver and/or a sense amplifier depending on an operating mode thereof. In some embodiments, the word line WL of the selected memory block may be referred to as a local word line.

The control logic circuit 14 may generate various control signals to program data into the memory cell array 11, read data from the memory cell array 11, and/or erase data stored in the memory cell array 11, based on a command CMD, an address ADDR, and a control signal CTRL. For example, the control logic circuit 14 may output the row address X-ADDR and the column address Y-ADDR. Accordingly, the control logic circuit 14 may generally control various operations within the memory device 10. In some embodiments, the control logic circuit 14 may include a common source line driver, and the common source line driver may be connected to the memory cell array 11 through a common source line CSL. The common source line driver may apply a common source voltage (e.g., a power voltage) and/or a ground voltage to the common source line CSL based on a control signal of the control logic circuit 14.

The I/O circuit 16 may be connected to the page buffer 15 through data lines DATA and may be connected to the outside through I/O lines. The I/O circuit 16 may receive data to be programmed into a selected memory cell of the memory cell array 11 from the outside during a program operation, and/or may transmit data read from the selected memory cell to the outside during a read operation.

In the embodiment, the memory device 10 may include a cell region and a peripheral circuit region. Herein, the cell region may refer to a region in which the memory cell array 11, row lines and column lines, which may be connected to the memory cell array 11, are arranged. The peripheral circuit region may refer to a region in which circuit elements configuring the peripheral circuit PECT are arranged.

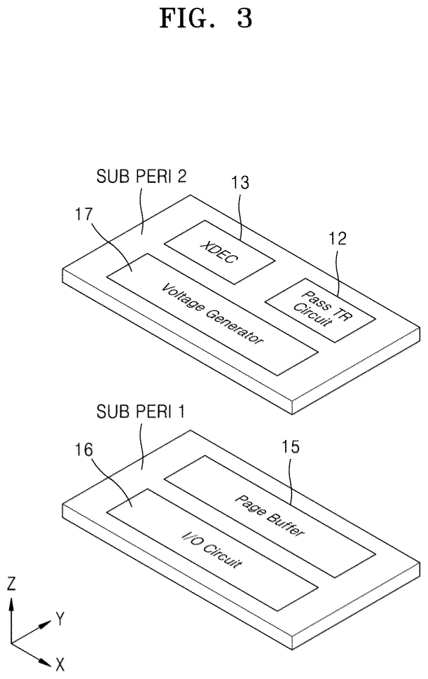

As described below, the peripheral circuit region, according to an embodiment, may be arranged to overlap the cell region in a vertical direction. Accordingly, the peripheral circuit region may overlap the cell region in a plan view. In addition, the peripheral circuit region, according to an embodiment, may include a plurality of sub-peripheral circuit regions stacked in the vertical direction. That is, the peripheral circuit region may be formed in multiple layers. Accordingly, compared to a peripheral circuit region in a single layer, an area occupied by the peripheral circuit region, according to an embodiment in a plan view, may be reduced. In addition, the thicknesses of lowermost inter-layer dielectric (ILD) regions of the plurality of sub-peripheral circuit regions, according to an embodiment, may be different from each other. According to the present disclosure, in a memory device including two or more sub-peripheral circuit regions, when an I/O circuit and a row decoder circuit are respectively formed in different sub-peripheral circuit regions, the thicknesses of the lowermost ILD regions may be varied to improve the performance and degree of integration of each circuit, as described below with reference to FIG. 3.

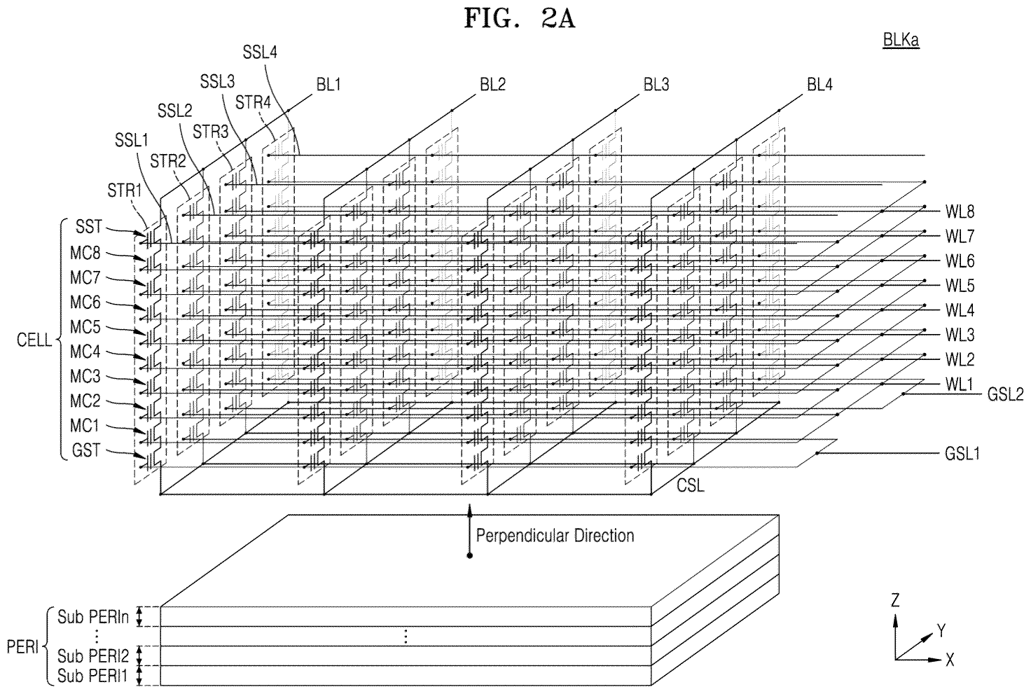

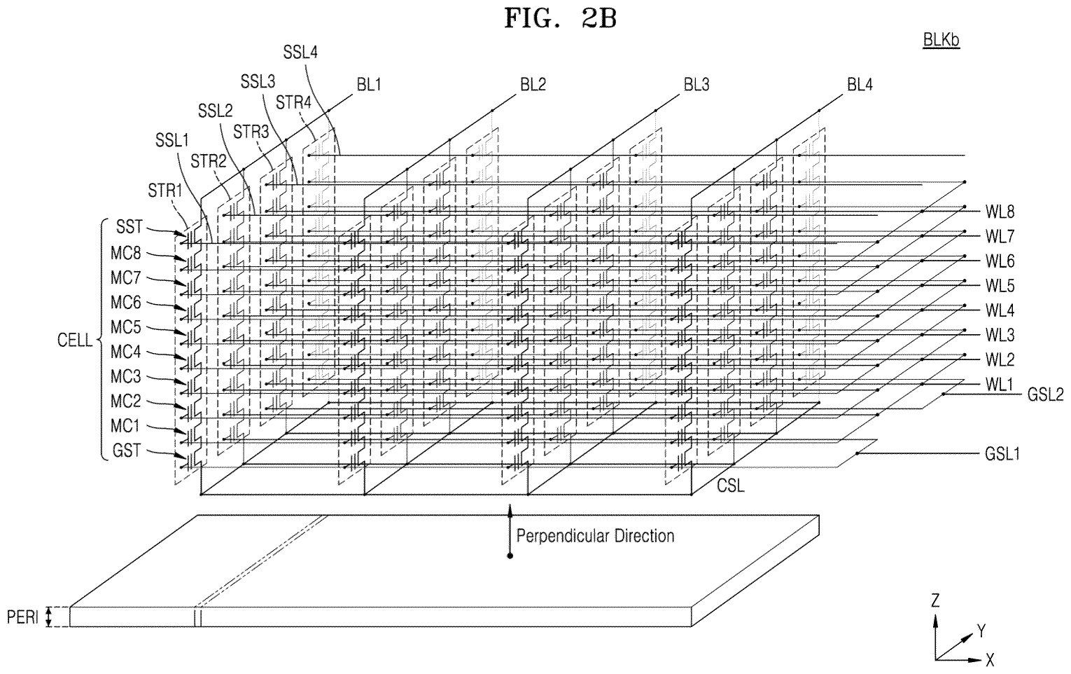

FIG. 2A is a diagram showing an example of a memory block BLKa from among the memory blocks included in the memory cell array 11 of FIG. 1 and a peripheral circuit corresponding to the memory block BLKa, according to an embodiment. FIG. 2B is a diagram showing an example of a memory block BLKb according to a comparative example and a peripheral circuit corresponding to the memory block BLKb, according to an embodiment.

Referring to FIG. 2A, the memory block BLKa may include a plurality of strings STR (e.g., a first string STR1, a second string STR2, a third string STR3, and a fourth string STR4) arranged in rows and columns. The plurality of strings STR may be commonly connected to the common source line CSL. FIG. 2A shows that the common source line CSL is connected to the lower end of the plurality of strings STR. However, it may be sufficient that the common source line CSL is electrically connected to the lower end of the plurality of strings STR, and it may not be limited to being physically located at the lower end of the plurality of strings STR. For example, FIG. 2A shows that the plurality of strings STR are arranged in a 4×4 format, however, the memory block BLKa may include less (e.g., three (3) or less) or more (e.g., five (5) or more) strings.

The strings in each row may be commonly connected to a ground selection line (e.g., a first ground selection line GSL1 or a second ground selection line GSL2). For example, the strings in first and/or second rows may be commonly connected to the first ground selection line GSL1, and the strings in third and/or fourth rows may be commonly connected to the second ground selection line GSL2. However, the present disclosure is not limited thereto. For example, four (4) different ground selection lines may be provided, and the strings in each row may also be implemented to be connected to different ground selection lines.

The strings in each row may be connected to corresponding string selection lines from among a plurality of string selection lines (e.g., a first string selection line SSL1, a second string selection line SSL2, a third string selection line SSL3, and a fourth string selection line SSL4). The strings in each column may be connected to a corresponding bit line from among a plurality of bit lines (e.g., a first bit line BL1, a second bit line BL2, a third bit line BL3, and a fourth bit line BL4).

Each string of plurality of strings STR may include at least one ground selection transistor GST connected to the first or second ground selection line GSL1 or GSL2, a plurality of memory cells (e.g., a first memory cell MC1, a second memory cell MC2, a third memory cell MC3, a fourth memory cell MC4, a fifth memory cell MC5, a sixth memory cell MC6, a seventh memory cell MC7, an eighth memory cell MC8) respectively connected to a plurality of word lines (e.g., a first word line WL1, a second word line WL2, a third word line WL3, a fourth word line WLA, a fifth word line WL5, a sixth word line WL6, a seventh word line WL7, and an eighth word line WL8), and string selection transistors SST respectively connected to the plurality of string selection lines SSL1 to SSL4.

In each string of the plurality of strings STR, the ground selection transistor GST, the plurality of memory cells MC1 to MC8, and the string selection transistors SST may be connected in series in a direction perpendicular to the peripheral circuit region and may be sequentially stacked in the direction perpendicular to the peripheral circuit region. In each string of the plurality of strings STR, at least one of the plurality of memory cells MC1 to MC8 may be used as a dummy memory cell. The dummy memory cell may not be programmed (e.g., program-inhibited) and/or may be differently programmed from the remaining memory cells of the plurality of memory cells MC1 to MC8.

Continuing to refer to FIG. 2A, at least a portion of the peripheral circuit PECT may be arranged at the lower end of the memory block BLKa. Circuit elements of the peripheral circuit PECT, which may be arranged at the lower end of the memory block BLKa, may form a peripheral circuit region PERI.

In an embodiment, the peripheral circuit region PERI may include a plurality of sub-peripheral circuit regions (e.g., a first sub-peripheral circuit region Sub PERI1, a second sub-peripheral circuit region Sub PERI2, to an n-th sub-peripheral circuit region Sub PERIn, wherein n is a positive integer greater than one (1)), each sub-peripheral circuit region extending in a first direction (X axis direction) and a second direction (Y axis direction). The plurality of sub-peripheral circuit regions Sub PERI1 to Sub PERIn may be stacked in a third direction (Z axis direction). Accordingly, an area occupied by the peripheral circuit region PERI in a plan view may be reduced, when compared to related memory devices.

According to a comparative example, elements of a peripheral circuit PECT may be arranged at the lower end of the memory block BLKb in a single layer to form the peripheral circuit region PERI, as shown in FIG. 2B. In the case of the peripheral circuit region being formed in a single layer, all circuit elements configuring a peripheral circuit may be arranged along a plane defined by the first and second directions (X axis and Y axis directions) at a substantially similar and/or the same height. As the number of word lines in a memory block increases, an area occupied by a cell region in a plan view may be gradually reduced to provide the same capacity, while an area occupied by a peripheral circuit region may remain unchanged. That is, as the number of word lines increases, the proportion of area occupied in a plan view by a peripheral circuit region formed in a single layer may increase.

For example, as shown in FIG. 2B, when viewed in a plan view, a region where the memory cells of a cell region are not arranged and only circuit elements of a peripheral circuit region are arranged may gradually increase. Accordingly, a wasted space in which the memory cells of the cell region are not arranged may increase, and miniaturization of the memory device may prove to be difficult.

Alternatively, as shown in FIG. 2A, the peripheral circuit region PERI, according to an embodiment, may include the plurality of sub-peripheral circuit regions (e.g., the plurality of sub-peripheral circuit regions Sub PERI1 to Sub PERIn), and the plurality of sub-peripheral circuit regions Sub PERI1 to Sub PERIn may be stacked in the third direction (Z axis direction). Accordingly, when compared to a peripheral circuit region in a single layer, an area occupied by the peripheral circuit region PERI, according to an embodiment in a plan view, may be reduced. Consequently, the wasted space may be reduced, and the memory device 10 may be miniaturized, when compared to a related memory device.

FIG. 3 is a diagram of an example of circuits arranged in sub-peripheral circuit regions.

Referring to FIG. 3, circuits respectively arranged in a first sub-peripheral circuit region SUB PERI1 and a second sub-peripheral circuit region SUB PERI2 are shown. According to an embodiment, the first sub-peripheral circuit region SUB PERI1 and the second sub-peripheral circuit region SUB PERI2, as shown in FIG. 3, may be and/or may include the sub-peripheral circuit regions included in the peripheral circuit region PERI described with reference to FIG. 2A. According to an embodiment, the first sub-peripheral circuit region SUB PERI1 and the second sub-peripheral circuit region SUB PERI2 may be sequentially stacked. According to another embodiment, the first sub-peripheral circuit region SUB PERI1 and the second sub-peripheral circuit region SUB PERI2 may also be stacked with other sub-peripheral circuit regions arranged therebetween. FIG. 3 shows that the first sub-peripheral circuit region SUB PERI1 and the second sub-peripheral circuit region SUB PERI2 have the same area, however, the present disclosure is not limited in this regard. For example, the first sub-peripheral circuit region SUB PERI1 and the second sub-peripheral circuit region SUB PERI2 may be formed with different areas. FIG. 3 shows that the first sub-peripheral circuit region SUB PERI1 is formed below the second sub-peripheral circuit region SUB PERI2, however, the present disclosure is not limited in this regard. For example, the first sub-peripheral circuit region SUB PERI1 may be formed above the second sub-peripheral circuit region SUB PERI2.

Referring to FIG. 3, the page buffer 15 and the I/O circuit 16 may be arranged in the first sub-peripheral circuit region SUB PERI1. The row decoder 13, the pass transistor circuit 12, and a voltage generator 17 may be arranged in the second sub-peripheral circuit region SUB PERI2. According to an embodiment, the row decoder 13, the pass transistor circuit 12, the page buffer 15, and the I/O circuit 16 may correspond to the components included in the peripheral circuit PECT described with reference to FIG. 1. The voltage generator 17 may generate various types of internal voltages for performing program operations, read operations, erase operations, or the like on the memory cell array 11. For example, the voltage generator 17 may generate a word line voltage, a program voltage, a read voltage, a pass voltage, an erase verification voltage, a program verification voltage, or the like. According to an embodiment, the I/O circuit 16 may include transistors for high-speed operations. According to an embodiment, the pass transistor circuit 12 may include a plurality of pass transistors connected to a high-voltage metal applying a high voltage.

According to the present disclosure, the I/O circuit 16 may include a serializer-deserializer (SerDes), a data-path circuit, or the like connected to a data queue (DQ) pad that may need to perform a high-speed operation, and the pass transistor circuit 12 and the row decoder 13 may include a row decoder driver, which may be connected to a word line and may need a high-voltage operation for implementation of high-integration NAND memory, may respectively be implemented on different layers. According to an embodiment, the I/O circuit 16 may be implemented in the first sub-peripheral circuit region SUB PERI1, and the row decoder 13 and the pass transistor circuit 12 may be implemented in the second sub-peripheral circuit region SUB PERI2. According to an embodiment, the I/O circuit 16 implemented in the first sub-peripheral circuit region SUB PERI1 may be a circuit that may need to perform a high-speed operation and may be connected to pad connected to a package pin, and may include other circuits in addition to the circuit described above. The row decoder 13 implemented in the second sub-peripheral circuit region SUB PERI2 may be and/or may include a circuit that may need to perform a high-voltage operation to drive a word line of a memory cell region, and may include other circuits in addition to the circuit described above.

According to an embodiment, the thickness of a lowermost ILD region of the first sub-peripheral circuit region SUB PERI1 and the thickness of a lowermost ILD region of the second sub-peripheral circuit region SUB PERI2, in which different circuits are respectively arranged, may be different from each other. According to an embodiment, the thickness of the lowermost ILD region of the first sub-peripheral circuit region SUB PERI1 may have a smaller value than the thickness of the lowermost ILD region of the second sub-peripheral circuit region SUB PERI2. That is, the thickness of the lowermost ILD region of a wafer corresponding to the first sub-peripheral circuit region SUB PERI1 including the I/O circuit 16 may have a smaller value than the thickness of the lowermost ILD region of a wafer corresponding to the second sub-peripheral circuit region SUB PERI2 including the row decoder 13 and the pass transistor circuit 12.

According to an embodiment, as the thickness of the lowermost ILD region of the wafer corresponding to the first sub-peripheral circuit region SUB PERI1 including the I/O circuit 16 is reduced, the pull down time (tPD) of the corresponding transistor may be reduced to facilitate a high-speed operation. According to an embodiment, as the thickness of the lowermost ILD region of the wafer corresponding to the second sub-peripheral circuit region SUB PERI2 including the row decoder 13 and the pass transistor circuit 12 may be increased, an influence of electric field (E-field) due to a high voltage difference between the lowermost metal pattern and the channel of a transistor formed in an active region may be reduced, and thus the performance of the transistor may be improved, when compared to a related memory device.

According to an embodiment, circuits needing to perform high-speed operations, such as, but not limited to, a page buffer and an I/O circuit, may be arranged in the first sub-peripheral circuit region SUB PERI1, and circuits needed to perform high-voltage operations, such as, but not limited to, a row decoder and a pass transistor circuit, may be arranged in the second sub-peripheral circuit region SUB PERI2.

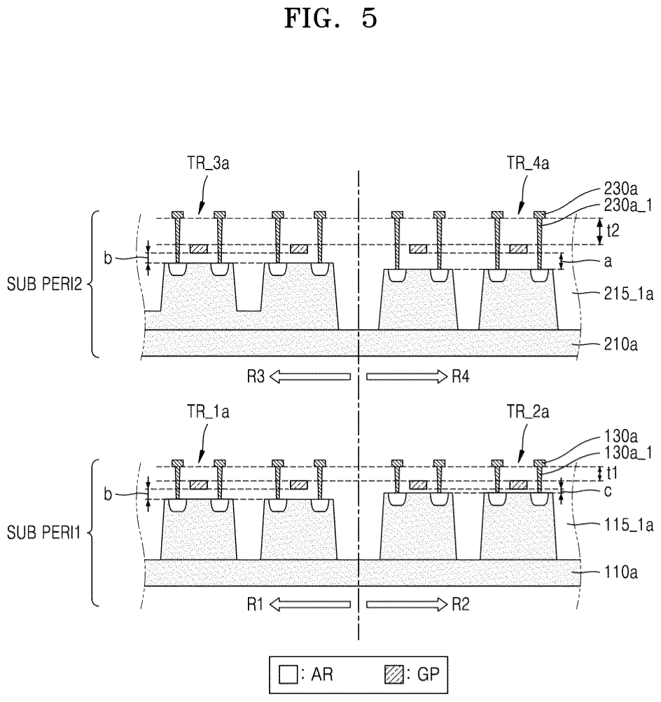

In the present disclosure, the structure of a memory device may be optimized compared to the comparative example by arranging circuits having different characteristics as described above in peripheral circuit regions on different layers and differently forming the thicknesses of respective lowermost ILD regions. That is, an I/O circuit for a high-speed operation and a circuit including high-voltage transistors with significant interference between a metal pattern and an active area may be arranged in different peripheral circuit regions, and the thicknesses of the lowermost ILD regions of respective peripheral circuit regions and a contact structure of the regions may be optimized, as described below with reference to FIG. 5.

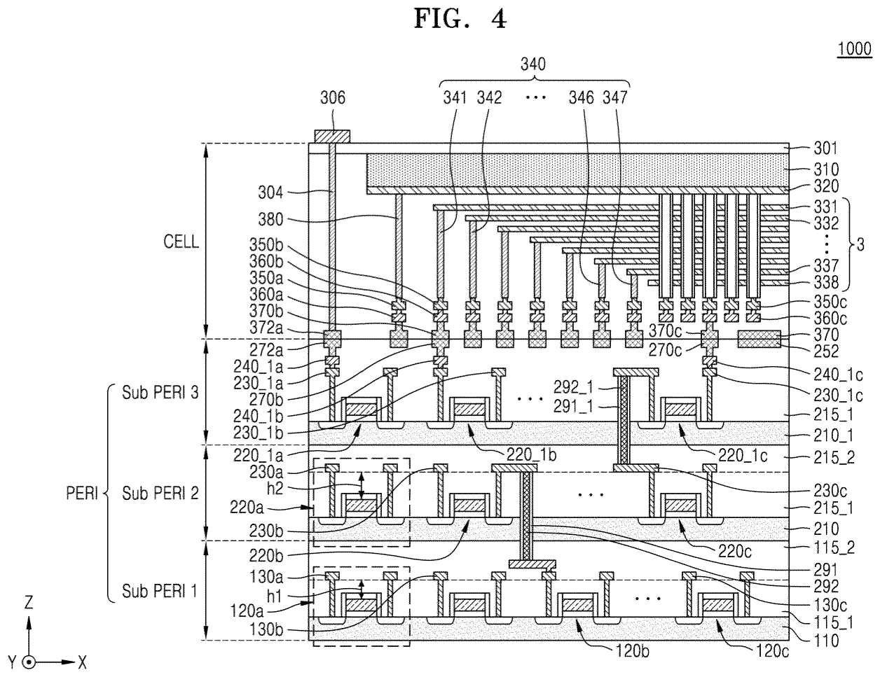

FIG. 4 is a cross-sectional view showing an example of a memory device 1000, according to an embodiment.

According to an embodiment, the memory device 1000 may have a chip-to-chip (C2C) structure. As used herein, the C2C structure may refer to a structure formed by manufacturing at least one upper chip including a cell region CELL and at least one lower chip including a peripheral circuit region PERI and then connecting the at least one upper chip to the at least one lower chip by a bonding method. For example, the bonding method may refer to a method of electrically and/or physically connecting a bonding metal pattern formed on the uppermost metal layer of the upper chip to a bonding metal pattern formed on the uppermost metal layer of the lower chip. For example, when the bonding metal patterns described above include copper (Cu), the bonding method may be a Cu-Cu bonding method. As another example, the bonding metal patterns described above may include other materials, such as, but not limited to, aluminum (Al), tungsten (W), or the like.

Referring to FIG. 4, the memory device 1000 may have a C2C structure in which an upper chip including the cell region CELL and a lower chip including the peripheral circuit region PERI may be connected to each other by a bonding method. The peripheral circuit region PERI of the lower chip may include first to third sub-peripheral circuit regions Sub PERI1 to Sub PERI3, which may be stacked in a third direction (Z axis direction). However, the present disclosure is not limited thereto. For example, the number of sub-peripheral circuit regions, which may be vertically stacked, is not limited thereto. In addition, FIG. 4 shows that the peripheral circuit region PERI is formed as a single chip. However, the present disclosure is not limited in this regard. For example, the peripheral circuit region PERI may be formed as two (2) or more chips, and each of the sub-peripheral circuit regions may also be formed as a single chip as separated.

The first sub-peripheral circuit region SUB PERI1 may include a first substrate 110 and a plurality of circuit elements (e.g., a first circuit element 120a, a second circuit element 120b, and a third circuit element 120c) that may be formed on the first substrate 110. The first substrate 110 may be a semiconductor substrate having a plate shape extended along a plane defined by first and second directions (X-axis direction and Y-axis direction). For example, the first substrate 110 may be a bulk silicon (Si) substrate, a silicon-on-insulator (SOI) substrate, or the like.

The second sub-peripheral circuit region SUB PERI2 may include a second substrate 210 and a plurality of circuit elements (e.g., a fourth circuit element 220a, a fifth circuit element 220b, and a sixth circuit element 220c) that may be formed on the second substrate 210. The second substrate 210 may include a different material from that of the first substrate 110. For example, the first substrate 110 may be a bulk silicon substrate, and the second substrate 210 may be doped polysilicon or an epitaxial thin film.

Some of the circuit elements of the first sub-peripheral circuit region SUB PERI1 may be electrically connected to some of the circuit elements of the second sub-peripheral circuit region SUB PERI2. For example, the second circuit element 120b of the first sub-peripheral circuit region SUB PERI1 may be connected to the fifth circuit element 220b of the second sub-peripheral circuit region SUB PERI2 by a through electrode 292.

The through electrode 292 may penetrate the second substrate 210. An upper surface of the through electrode 292 may be in contact with one of lowermost metal patterns (e.g., a fourth lowermost metal pattern 230a, a fifth lowermost metal pattern 230b, and a sixth lowermost metal pattern 230c) of the second sub-peripheral circuit region SUB PERI2. A lower surface of the through electrode 292 may be in contact with one of lowermost metal patterns (e.g., a first lowermost metal pattern 130a, a second lowermost metal pattern 130b, and a third lowermost metal pattern 130c) of the first sub-peripheral circuit region SUB PERI1. The entirety or a portion of the side surface of the through electrode 292 may be surrounded by a through electrode insulating layer 291.

Similarly, the third sub-peripheral circuit region Sub PERI3 may include a third substrate 210_1 and a plurality of circuit elements (e.g., a seventh circuit element 220_1a, an eighth circuit element 220_1b, and a ninth circuit element 220_1c) that may be formed on the third substrate 210_1, and a circuit element of the third sub-peripheral circuit region Sub PERI3 may be connected to a circuit element of the second sub-peripheral circuit region SUB PERI2 by a through electrode 292_1. Accordingly, the first sub-peripheral circuit region SUB PERI1 may be electrically connected to the third sub-peripheral circuit region Sub PERI3 through the through electrodes 292 and 292_1, and may also be electrically connected to the cell region CELL through the third sub-peripheral circuit region Sub PERI3.

Continuing to refer to FIG. 4, the first sub-peripheral circuit region SUB PERI1 may include the first substrate 110, a first insulating layer 115_1, and a second insulating layer 115_2. According to an embodiment, the first insulating layer 115_1 may refer to an insulating layer region between the first substrate 110 and a lower end portion of a circuit element, in which the third lowermost metal pattern 130c is formed. The second insulating layer 115_2 may mean an insulating layer region formed in a region from the lower end portion of the third lowermost metal pattern 130c to the second sub-peripheral circuit region SUB PERI2. According to an embodiment, the thickness of a region between an upper end portion of a gate pattern of the first circuit element 120a and the lower end portion of the first lowermost metal pattern 130a among the height of the first insulating layer 115_1 may be the thickness of a lowermost ILD region in the first sub-peripheral circuit region SUB PERI1. According to an embodiment, the thickness of the lowermost ILD region of the circuit element included in the first sub-peripheral circuit region SUB PERI1 may be h1.

As shown in FIG. 4, the second sub-peripheral circuit region SUB PERI2 may include the second substrate 210, a third insulating layer 215_1, and a fourth insulating layer 215_2. According to an embodiment, the third insulating layer 215_1 may refer to an insulating layer region between the second substrate 210 and a lower end portion of a circuit element, in which the sixth lowermost metal pattern 230c is formed. The fourth insulating layer 215_2 may refer to an insulating layer region formed in a region from the lower end portion of the sixth lowermost metal pattern 230c to the second sub-peripheral circuit region SUB PERI2. According to an embodiment, the thickness of a region between an upper end portion of a gate pattern of the circuit element 220a and a lower end portion of a lowermost metal pattern 230a among the height of the third insulating layer 215_1 may be the thickness of a lowermost ILD region in the second sub-peripheral circuit region SUB PERI2. According to an embodiment, the thickness of the lowermost ILD region of the circuit element included in the second sub-peripheral circuit region SUB PERI2 may be h2. According to an embodiment, h2 may have a greater value than h1.

According to a comparative example, when the number of word lines increases (e.g., due to increased demand for high-integration NAND), a difficulty of a burying operation may increase. In addition, with the development of technology, a needed I/O speed may increase. To this end, a reduction in contact resistance may be needed to reduce the pull down time (tPD) of a transistor. In addition, a NAND memory device may need to perform an operation of applying a relatively high voltage to a word line to secure threshold voltage (Vth) distribution in a memory operation using multi-value memories, such as, but not limited to, triple-level cell (TLC), quad-level cell (QLC), or the like, unlike other related memory devices. To this end, in a word line pass transistor region that may drive a word line, a strong electric field generated by a high voltage applied to a lowermost metal line may cause interference with an active channel, thereby potentially deteriorating transistor characteristics.

Accordingly, in the present disclosure, deterioration of the transistor characteristics may be prevented and/or reduced by reducing the thickness of the lowermost ILD region in a sub-peripheral circuit region in which an I/O circuit is arranged to secure the I/O speed, and thereby, increasing the thickness of the lowermost ILD region in a sub-peripheral circuit region in which a high-voltage transistor is arranged. Hereinafter, arrangement structures in sub-peripheral circuit regions having various embodiments satisfying the above conditions are described.

In the present disclosure, when the peripheral circuit region PERI is formed as a single chip as shown in FIG. 4, the peripheral circuit region PERI may include a plurality of sub-peripheral circuit regions, and the plurality of sub-peripheral circuit regions may respectively include lowermost ILD regions having different thicknesses from each other. In another embodiment, when the peripheral circuit regions PERI are formed as different chips, in the peripheral circuit regions arranged in different chips, thicknesses of the lowermost ILD regions thereof may different from each other.

In the following description with reference to FIGS. 5 to 10, the structures of elements respectively arranged in a first sub-peripheral circuit region and a second sub-peripheral circuit region included in the peripheral circuit region PERI are described. However, the description herein may be equally applied to a configuration in which the peripheral circuit regions PERI are formed as different first and second chips, a first peripheral circuit region is arranged in the first chip, and a second peripheral circuit region is arranged in the second chip. That is, the first peripheral circuit region may correspond to the first sub-peripheral circuit region, and the second peripheral circuit region may correspond to the second sub-peripheral circuit region. That is, in the present disclosure, the description of the first sub-peripheral circuit region and second sub-peripheral circuit region, which may be arranged in a single chip, may be equally applied to the description of the first peripheral circuit region and the second peripheral circuit region, which may be arranged in different chips.

FIG. 5 is a cross-sectional view of structures of elements respectively arranged in a first sub-peripheral circuit region and a second sub-peripheral circuit region, according to an embodiment.

Referring to FIG. 5, an example in which the first sub-peripheral circuit region SUB PERI1 and the second sub-peripheral circuit region SUB PERI2 are formed to be stacked is shown. The first sub-peripheral circuit region SUB PERI1 and the second sub-peripheral circuit region SUB PERI2 of FIG. 5 may include and/or may be similar in many respects to the first sub-peripheral circuit region SUB PERI1 and the second sub-peripheral circuit region SUB PERI2 described above with reference to FIGS. 3 and 4, respectively, and may include additional features not mentioned above. Consequently, repeated descriptions of the first sub-peripheral circuit region SUB PERI1 and the second sub-peripheral circuit region SUB PERI2 described above with reference to FIGS. 3 and 4 may be omitted for the sake of brevity.

Four (4) transistors may be respectively formed in the first sub-peripheral circuit region SUB PERI1 and the second sub-peripheral circuit region SUB PERI2. The first sub-peripheral circuit region SUB PERI1 may include a first transistor region R1 and a second transistor region R2. The second sub-peripheral circuit region SUB PERI2 may include a third transistor region R3 and a fourth transistor region R4. Although FIG. 5 shows that four (4) transistors are respectively formed in the first sub-peripheral circuit region SUB PERI1 and the second sub-peripheral circuit region SUB PERI2, the present disclosure is not limited in this regard. For example, four (4) or more transistors or circuit elements may be respectively arranged in the first sub-peripheral circuit region SUB PERI1 and the second sub-peripheral circuit region SUB PERI2 without departing from the scope of the present disclosure.

According to an embodiment, a first transistor TR_1a formed in the first transistor region R1 and a second transistor TR_2a formed in the second transistor region R2 may be transistors having different characteristics. According to an embodiment, the first transistor TR_1a formed in the first transistor region R1 of the first sub-peripheral circuit region SUB PERI1 may be a transistor having a slower speed than the second transistor TR_2a formed in the second transistor region R2 of the first sub-peripheral circuit region SUB PERI1. According to an embodiment, the second transistor TR_2a formed in the second transistor region R2 may be a high-speed transistor.

According to an embodiment, a third transistor TR_3a formed in the third transistor region R3 and a fourth transistor TR_4a formed in the fourth transistor region R4 may be transistors having different characteristics. According to an embodiment, the third transistor TR_3a formed in the third transistor region R3 of the second sub-peripheral circuit region SUB PERI2 may be a transistor having a lower voltage than the fourth transistor TR_4a formed in the fourth transistor region R4 of the second sub-peripheral circuit region SUB PERI2. According to an embodiment, the fourth transistor TR_4a formed in the fourth transistor region R4 may be a high voltage (HV) transistor.

The characteristics of the transistors respectively formed in the first transistor region R1, the second transistor region R2, the third transistor region R3, and the fourth transistor region R4 described above are not limited thereto, and transistors with various characteristics may be formed separately in respective regions within each sub-peripheral circuit region.

Referring to the example of FIG. 5, the first transistor TR_1a and the second transistor TR_2a formed in the first sub-peripheral circuit region SUB PERI1 may be respectively arranged in the first transistor region R1 and the second transistor region R2. A length b between the lower end portion of a gate pattern GP of the first transistor TR_1a and the upper end portion of a substrate 110a in which an active region AR is formed may be greater than a length c between the lower end portion of a gate pattern GP of the second transistor TR_2a and the upper end portion of the substrate 110a in which the active region AR is formed.

Referring to the example of FIG. 5, the third transistor TR_3a and the fourth transistor TR_4a formed in the second sub-peripheral circuit region SUB PERI2 may be respectively arranged in the third transistor region R3 and the fourth transistor region R4. The length b between the lower end portion of the gate pattern GP of the third transistor TR_3a and the upper end portion of a substrate 210a in which the active region AR is formed may be less than a length a between the lower end portion of the gate pattern GP of the fourth transistor TR_4a and the upper end portion of the substrate 210a in which the active region AR is formed. According to an embodiment, a length between the lower end portion of the gate pattern GP of a transistor and the upper end portion of the substrate 210a in which the active region AR is formed may be the thickness of gate oxide formed at the lower end portion of the gate pattern GP.

Continuing to refer to FIG. 5, transistors arranged in different transistor regions in a sub-peripheral circuit region, which are disposed on the same layer, may have gate oxide having different thicknesses from each other.

In the present disclosure, the thickness of the lowermost ILD region may refer to the thickness between the upper end portion of the gate pattern GP of a corresponding transistor and a metal pattern formed at the lowermost end in an insulator region in which the corresponding transistor is formed. Referring to FIG. 5, the thickness of the lowermost ILD region of each of the first transistor TR_1a and the second transistor TR_2a formed in the first sub-peripheral circuit region SUB PERI1 may be t1. According to an embodiment, the thickness of the lowermost ILD region of the second transistor TR_2a may correspond to the thickness between the upper end portion of the gate pattern GP of the second transistor TR_2a and the lower end portion of the lowermost metal pattern 130a formed at the lowermost end in an insulator region 115_1a in which the second transistor TR_2a is formed.

According to an embodiment, the thickness of the lowermost ILD region of each of the third transistor TR_3a and the fourth transistor TR_4a formed in the second sub-peripheral circuit region SUB PERI2 may be t2. According to an embodiment, the thickness of the lowermost ILD region of the fourth transistor TR_4a may correspond to the thickness between the upper end portion of the gate pattern GP of the fourth transistor TR_4a and the lower end portion of the lowermost metal pattern 230a formed at the lowermost end in an insulator region 215_1a in which the fourth transistor TR_4a is formed.

According to an embodiment, the thickness t2 of the lowermost ILD region of each of the third transistor TR_3a and the fourth transistor TR_4a formed in the second sub-peripheral circuit region SUB PERI2 may have a greater value than the thickness t1 of the lowermost ILD region of each of the first transistor TR_1a and the second transistor TR_2a formed in the first sub-peripheral circuit region SUB PERI1. According to an embodiment, the thicknesses of the lowermost ILD regions of the first transistor TR_1a and the second transistor TR_2a respectively arranged in different transistor regions (e.g., the first transistor region R1 and the second transistor region R2) included in the first sub-peripheral circuit region SUB PERI1 may be equal to t1. According to an embodiment, the thicknesses of the lowermost ILD regions of the third transistor TR_3a and the fourth transistor TR_4a respectively arranged in different transistor regions (e.g., the third transistor region R3 and the fourth transistor region R4) included in the second sub-peripheral circuit region SUB PERI2 may be equal to t2.

According to an embodiment, a plurality of transistors included in one sub-peripheral circuit region may respectively include gate oxides of different thicknesses, however, the thicknesses of the lowermost ILD regions thereof may be the same.

According to an embodiment, the pull down time (tPD) of an I/O circuit may be secured and lines of word line pass transistors may be secured by separately arranging the I/O circuit requiring high speed and a pass transistor circuit requiring high voltage in a multi-peripheral circuit structure including a plurality of sub-peripheral circuit regions and varying the thicknesses of lowermost ILD regions of the sub-peripheral circuit regions, which may be separately arranged.

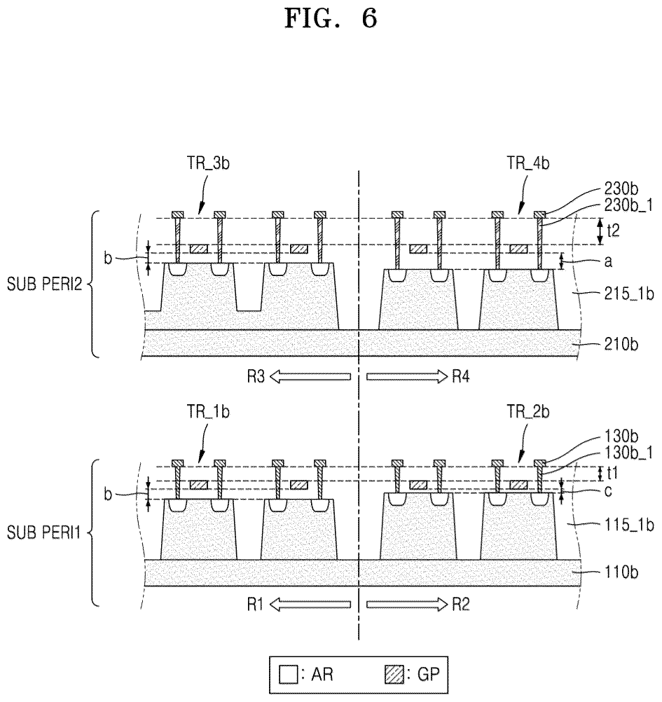

FIG. 6 is a cross-sectional view of structures of elements respectively arranged in a first sub-peripheral circuit region and a second sub-peripheral circuit region, according to an embodiment. The first sub-peripheral circuit region SUB PERI1 and the second sub-peripheral circuit region SUB PERI2 of FIG. 6 may include and/or may be similar in many respects to the first sub-peripheral circuit region SUB PERI1 and the second sub-peripheral circuit region SUB PERI2 described above with reference to FIGS. 3 to 5, respectively, and may include additional features not mentioned above. Consequently, repeated descriptions of the first sub-peripheral circuit region SUB PERI1 and the second sub-peripheral circuit region SUB PERI2 described above with reference to FIGS. 3 to 5 may be omitted for the sake of brevity.

Referring to FIG. 6, an example in which the first sub-peripheral circuit region SUB PERI1 and the second sub-peripheral circuit region SUB PERI2 are formed to be stacked is shown.

A first transistor TR_1b and a second transistor TR_2b may be arranged in the first sub-peripheral circuit region SUB PERI1, and a third transistor TR_3b and a fourth transistor TR_4b may be arranged in the second sub-peripheral circuit region SUB PERI2. According to an embodiment, descriptions of the first transistor TR_1b, the second transistor TR_2b, the third transistor TR_3b, and the fourth transistor TR_4b may respectively correspond to the descriptions of the first transistor TR_1a, the second transistor TR_2a, the third transistor TR_3a, and the fourth transistor TR_4a given above with reference to FIG. 5, and consequently, repeated descriptions may be omitted for the sake of brevity.

Referring to FIG. 6, the active region AR of the second transistor TR_2b may be connected to the lowermost metal pattern 130 through a first contact 130b_1. The active region AR of the fourth transistor TR_4b may be connected to the lowermost metal pattern 230b through a second contact 230b_1.

According to an embodiment, the first contact 130b_1 and the second contact 230b_1 may include different materials. According to an embodiment, the first contact 130b_1 may include, but not be limited to, cobalt silicide (CoSiₓ). According to an embodiment, the second contact 230b_1 may include, but not be limited to, titanium silicide (TiSiₓ). According to an embodiment, the first contact 130b_1 and the second contact 230b_1 may include different silicide materials.

According to an embodiment, cobalt silicide (CoSiₓ) may improve contact resistance compared to titanium silicide (TiSiₓ). As the first contact 130b_1 included in the first sub-peripheral circuit region SUB PERI1 and requiring high-speed output may include cobalt silicide (CoSiₓ), the pull down time tPD of the first sub-peripheral circuit region SUB PERI1 having a relatively thin thickness of the lowermost ILD region may be improved, when compared to a related memory device. As the second contact 230b_1 included in the second sub-peripheral circuit region SUB PERI2 may include titanium silicide (TiSiₓ), silicide recess control may be smoothly performed in the second sub-peripheral circuit region SUB PERI2 having a relatively thick thickness of the lowermost ILD region.

Referring to the embodiments of FIGS. 5 and 6, the pull down time tPD of the first sub-peripheral circuit region SUB PERI1 in which an I/O circuit needing to perform a high-speed operation is arranged may be improved and the deterioration of characteristics of transistors of the second sub-peripheral circuit region SUB PERI2 in which pass transistor circuits requiring high-voltage application is arranged may be improved by differently forming the thicknesses of the lowermost ILD regions of the first sub-peripheral circuit region SUB PERI1 and the second sub-peripheral circuit region SUB PERI2.

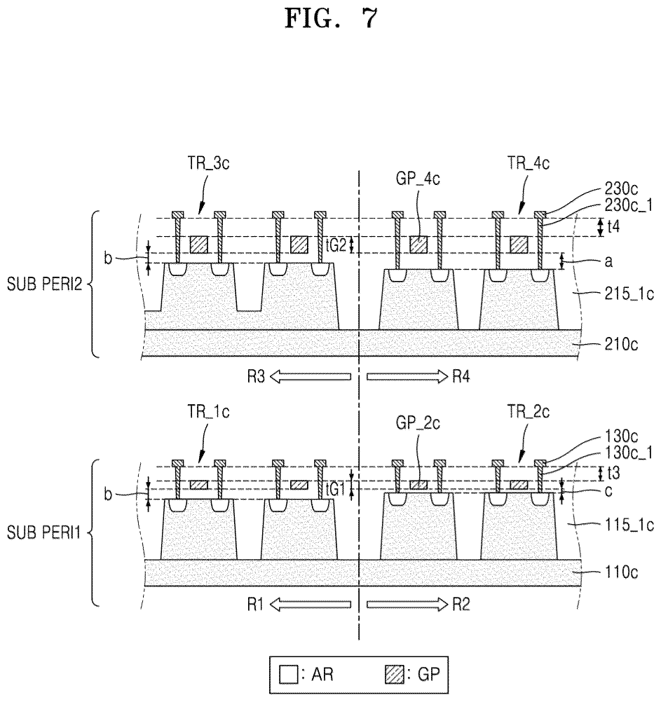

FIG. 7 is a cross-sectional view of structures of elements respectively arranged in a first sub-peripheral circuit region and a second sub-peripheral circuit region, according to an embodiment. The first sub-peripheral circuit region SUB PERI1 and the second sub-peripheral circuit region SUB PERI2 of FIG. 7 may include and/or may be similar in many respects to the first sub-peripheral circuit region SUB PERI1 and the second sub-peripheral circuit region SUB PERI2 described above with reference to FIGS. 3 to 6, respectively, and may include additional features not mentioned above. Consequently, repeated descriptions of the first sub-peripheral circuit region SUB PERI1 and the second sub-peripheral circuit region SUB PERI2 described above with reference to FIGS. 3 to 6 may be omitted for the sake of brevity.

A first transistor TR_1c and a second transistor TR_2c may be arranged in the first sub-peripheral circuit region SUB PERI1, and a third transistor TR_3c and a fourth transistor TR_4c may be arranged in the second sub-peripheral circuit region SUB PERI2.

Referring to FIG. 7, the thickness of a gate pattern of each of the first transistor TR_1c and the second transistor TR_2c included in the first sub-peripheral circuit region SUB PERI1 may be different from the thickness of a gate pattern of each of the third transistor TR_3c and the fourth transistor TR_4c included in the second sub-peripheral circuit region SUB PERI2.

Referring to FIG. 7, the thickness of the gate pattern of each of the first transistor TR_1c and the second transistor TR_2c may be tG1. The thickness of the gate pattern of each of the third transistor TR_3c and the fourth transistor TR_4c may be tG2. According to an embodiment, tG2 may have a greater value than tG1. According to an embodiment, the second transistor TR_2c may include a transistor including a thin gate oxide, and the fourth transistor TR_4c may include a transistor including a thick gate oxide.

Referring to FIG. 7, the thickness of the lowermost ILD region of each of the first transistor TR_1c and the second transistor TR_2c included in the first sub-peripheral circuit region SUB PERI1 may be t3, and the thickness of the lowermost ILD region of each of the third transistor TR_3c and the fourth transistor TR_4c included in the second sub-peripheral circuit region SUB PERI2 may be t4. According to an embodiment, t4 may have a greater value than t3.

Referring to FIG. 7, the thicknesses of the lowermost ILD regions of the first sub-peripheral circuit region SUB PERI1 and the second sub-peripheral circuit region SUB PERI2 may be different from each other, and the thicknesses of gate patterns of transistors respectively included in the first sub-peripheral circuit region SUB PERI1 and the second sub-peripheral circuit region SUB PERI2 may be different from each other.

According to an embodiment, a transistor formed in the first sub-peripheral circuit region SUB PERI1 may be formed with a thin thickness of a gate pattern to secure process capability for a high-speed operation, and a transistor formed in the second sub-peripheral circuit region SUB PERI2 may be formed with a thick thickness of a gate pattern to reduce gate resistance by applying high voltage.

According to another embodiment, the material of the gate pattern of the transistor formed in the first sub-peripheral circuit region SUB PERI1 may be different from the material of the gate pattern of the transistor formed in the second sub-peripheral circuit region SUB PERI2.

According to another embodiment, the gate stack structure of the gate pattern of the transistor formed in the first sub-peripheral circuit region SUB PERI1 may be different from the gate stack structure of the gate pattern of the transistor formed in the second sub-peripheral circuit region SUB PERI2.

According to an embodiment, the material of a contact of the transistor formed in the first sub-peripheral circuit region SUB PERI1 may be different from the material of a contact of the transistor formed in the second sub-peripheral circuit region SUB PERI2.

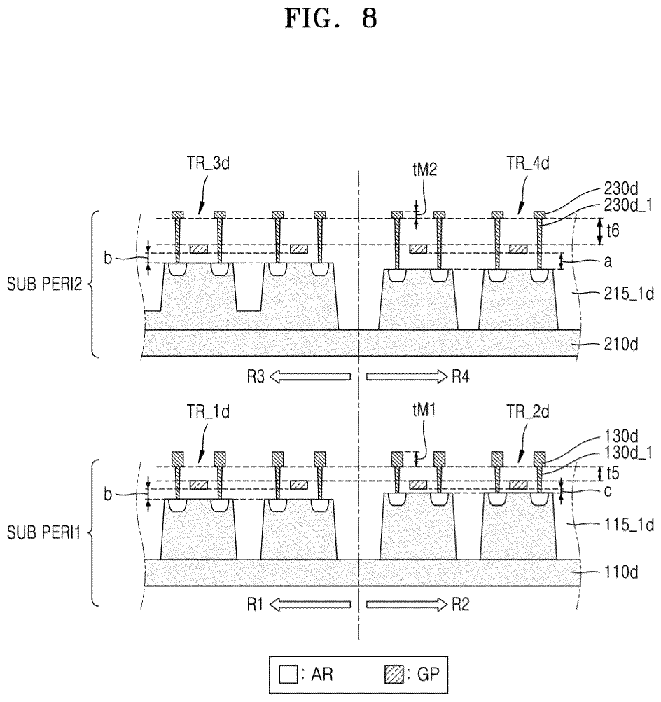

FIG. 8 is a cross-sectional view of structures of elements respectively arranged in a first sub-peripheral circuit region and a second sub-peripheral circuit region, according to an embodiment. The first sub-peripheral circuit region SUB PERI1 and the second sub-peripheral circuit region SUB PERI2 of FIG. 8 may include and/or may be similar in many respects to the first sub-peripheral circuit region SUB PERI1 and the second sub-peripheral circuit region SUB PERI2 described above with reference to FIGS. 3 to 7, respectively, and may include additional features not mentioned above. Consequently, repeated descriptions of the first sub-peripheral circuit region SUB PERI1 and the second sub-peripheral circuit region SUB PERI2 described above with reference to FIGS. 3 to 7 may be omitted for the sake of brevity.

A first transistor TR_1d and a second transistor TR_2d may be arranged in the first sub-peripheral circuit region SUB PERI1, and a third transistor TR_3d and a fourth transistor TR_4d may be arranged in the second sub-peripheral circuit region SUB PERI2.

According to an embodiment, a thickness tM1 of a lowermost metal pattern 130d of each of the first transistor TR_1d and the second transistor TR_2d included in the first sub-peripheral circuit region SUB PERI1 may be different from a thickness tM2 of a lowermost metal pattern 230d of each of the third transistor TR_3d and the fourth transistor TR_4d included in the second sub-peripheral circuit region SUB PERI2.

Referring to FIG. 8, a first contact 130d_1 extending in a vertical direction may be connected to the active region AR of the second transistor TR_2d, and the first contact 130d_1 may be in contact with the lowermost metal pattern 130d. According to an embodiment, the thickness of the lowermost metal pattern 130d connected to the second transistor TR_2d may be tM1.

Referring to FIG. 8, a second contact 230d_1 extending in the vertical direction may be connected to the active region AR of the fourth transistor TR_4d, and the second contact 230d_1 may be in contact with the lowermost metal pattern 230d. According to an embodiment, the thickness of the lowermost metal pattern 230d connected to the fourth transistor TR_4d may be tM2. The value of tM2 may be less than the value of tM1.

Referring to FIG. 8, the thickness of the lowermost ILD region of each of the first transistor TR_1d and the second transistor TR_2d included in the first sub-peripheral circuit region SUB PERI1 may be t5, and the thickness of the lowermost ILD region of each of the third transistor TR_3d and the fourth transistor TR_4d included in the second sub-peripheral circuit region SUB PERI2 may be t6. According to an embodiment, t6 may have a greater value than t5.

According to an embodiment, a transistor formed in the first sub-peripheral circuit region SUB PERI1 may be formed with a thick thickness of a metal pattern to secure process capability for an high-speed operation, and a transistor formed in the second sub-peripheral circuit region SUB PERI2 may be formed with a thick thickness of a lowermost ILD region for high voltage application, and thus the thickness of a metal pattern thereof may be formed to be thin to constantly maintain the height of a package.

According to an embodiment, the material of the metal pattern of the transistor formed in the first sub-peripheral circuit region SUB PERI1 may also be different from the material of the metal pattern of the transistor formed in the second sub-peripheral circuit region SUB PERI2.

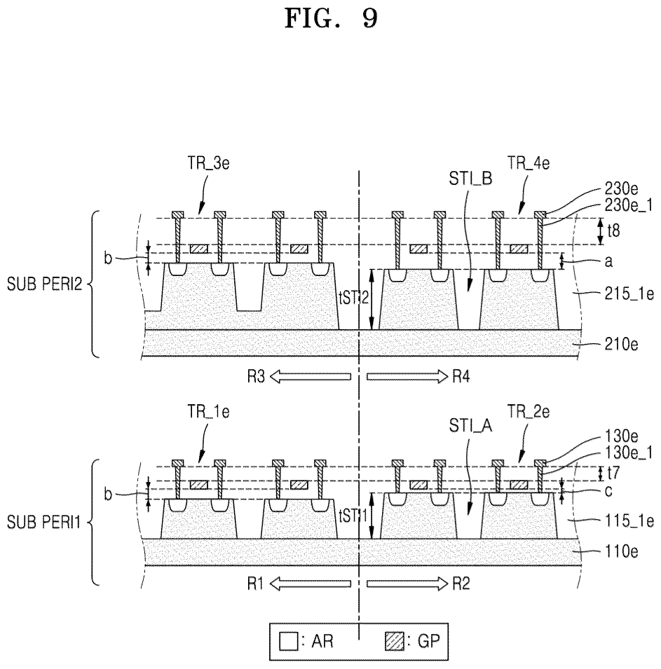

FIG. 9 is a cross-sectional view of structures of elements respectively arranged in a first sub-peripheral circuit region and a second sub-peripheral circuit region, according to an embodiment. The first sub-peripheral circuit region SUB PERI1 and the second sub-peripheral circuit region SUB PERI2 of FIG. 9 may include and/or may be similar in many respects to the first sub-peripheral circuit region SUB PERI1 and the second sub-peripheral circuit region SUB PERI2 described above with reference to FIGS. 3 to 8, respectively, and may include additional features not mentioned above. Consequently, repeated descriptions of the first sub-peripheral circuit region SUB PERI1 and the second sub-peripheral circuit region SUB PERI2 described above with reference to FIGS. 3 to 8 may be omitted for the sake of brevity.

A first transistor TR_1e and a second transistor TR_2e may be arranged in the first sub-peripheral circuit region SUB PERI1, and a third transistor TR_3e and a fourth transistor TR_4e may be arranged in the second sub-peripheral circuit region SUB PERI2.

According to an embodiment, the depth of a shallow trench isolation (STI) region STI_A formed on each of both sides of the second transistor TR_2e included in the first sub-peripheral circuit region SUB PERI1 may be different from the depth of an STI region STI_B formed on each of both sides of the fourth transistor TR_4e included in the second sub-peripheral circuit region SUB PERI2.

The first transistor TR_1e and the second transistor TR_2e may be disposed on a substrate 110e formed in the first sub-peripheral circuit region SUB PERI1, and STI regions STI_A separating transistors may be formed. The depth of the STI region STI_A formed in the second transistor region R2 of the first sub-peripheral circuit region SUB PERI1 may be tSTI1.

The third transistor TR_3e and the fourth transistor TR_4e may be disposed on a substrate 210e formed in the second sub-peripheral circuit region SUB PERI2, and STI regions STI_B separating transistors may be formed. The depth of the STI region STI_B formed in the fourth transistor region R4 of the second sub-peripheral circuit region SUB PERI2 may be tSTI2. According to an embodiment, the value of tSTI2 may be greater than the value of tSTI1.

Referring to FIG. 9, the thickness of the lowermost ILD region of each of the first transistor TR_1e and the second transistor TR_2e included in the first sub-peripheral circuit region SUB PERI1 may be t7), and the thickness of the lowermost ILD region of each of the third transistor TR_3e and the fourth transistor TR_4e included in the second sub-peripheral circuit region SUB PERI2 may be t8. According to an embodiment, t8 may have a greater value than t7.

According to an embodiment, a transistor formed in the first sub-peripheral circuit region SUB PERI1 may be formed with a shallow depth of an STI region to secure process capability for an high-speed operation, and a transistor formed in the second sub-peripheral circuit region SUB PERI2 may be formed with a thick thickness of a lowermost ILD region and a deep depth of an STI region for high voltage application, and thus the cost of manufacturing a mask may be reduced, when compared to a related memory device.

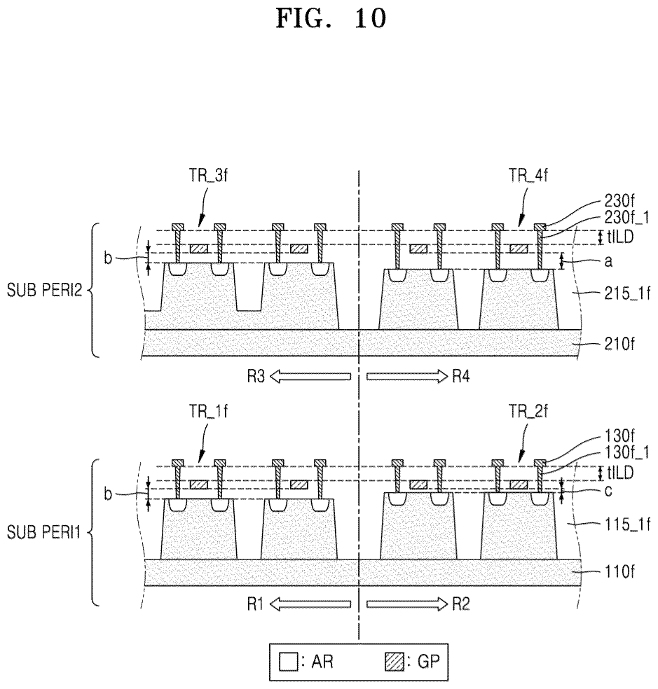

FIG. 10 is a cross-sectional view of structures of elements respectively arranged in a first sub-peripheral circuit region and a second sub-peripheral circuit region, according to a comparative example. The first sub-peripheral circuit region SUB PERI1 and the second sub-peripheral circuit region SUB PERI2 of FIG. 10 may include and/or may be similar in many respects to the first sub-peripheral circuit region SUB PERI1 and the second sub-peripheral circuit region SUB PERI2 described above with reference to FIGS. 3 to 9, respectively, and may include additional features not mentioned above. Consequently, repeated descriptions of the first sub-peripheral circuit region SUB PERI1 and the second sub-peripheral circuit region SUB PERI2 described above with reference to FIGS. 3 to 9 may be omitted for the sake of brevity.

A first transistor TR_1f and a second transistor TR_2f may be arranged in the first sub-peripheral circuit region SUB PERI1, and a third transistor TR_3f and a fourth transistor TR_4f may be arranged in the second sub-peripheral circuit region SUB PERI2.

According to an embodiment, the thickness of the lowermost ILD region of each of the first transistor TR_1f and the second transistor TR_2f may be tILD, and the thickness of the lowermost ILD region of each of the third transistor TR_3f and the fourth transistor TR_4f may be tILD.

That is, according to the comparative example, the thickness of the lowermost ILD region of each of the first transistor TR_1f and the second transistor TR_2f arranged in the first sub-peripheral circuit region SUB PERI1 may be equal to the thickness of the lowermost ILD region of each of the third transistor TR_3f and the fourth transistor TR_4f arranged in the second sub-peripheral circuit region SUB PERI2.

According to the present disclosure, unlike related memory devices, the thickness of a lowermost ILD region of a transistor in a first sub-peripheral circuit region may be formed to be different from the thickness of a lowermost ILD region of a transistor in a second sub-peripheral circuit region, and thus an optimized design structure considering characteristics of transistors, which have different characteristics, may be possible. According to the present disclosure, in a sub-peripheral circuit region including a transistor of an I/O circuit for a high-speed operation, the thickness of a lowermost ILD region may be reduced to improve the pull down time (tPD) to facilitate a silicide process, and in a sub-peripheral circuit region which may include word line pass transistors where a high-voltage metal passes through an active region, the thickness of a lowermost ILD region may be increased to reduce interference between a metal region and a channel region, thereby increasing line utilization.

In the embodiment, only a case where the thicknesses of the lowermost ILD regions of two (2) sub-peripheral circuit regions are different from each other is described, however, the present disclosure is not limited thereto, and the thicknesses of the lowermost ILD regions of three (3) or more sub-peripheral circuit regions may all be different.

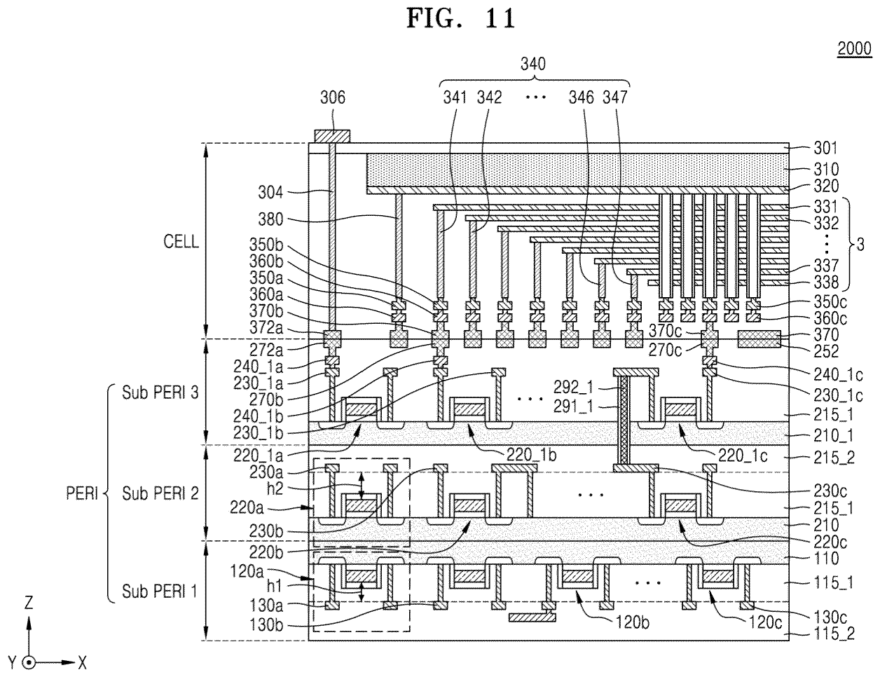

FIG. 11 is a cross-sectional view showing an example of a memory device 2000, according to an embodiment. The memory device 2000 of FIG. 11 may include and/or may be similar in many respects to the memory device 1000 described above with reference to FIG. 4, and may include additional features not mentioned above. Consequently, repeated descriptions of the memory device 2000 described above with reference to FIG. 4 may be omitted for the sake of brevity.

According to an embodiment, the peripheral circuit region PERI may include a first sub-peripheral circuit region SUB PERI1, a second sub-peripheral circuit region SUB PERI2, and a third sub-peripheral circuit region Sub PERI3.

According to an embodiment, a first substrate 110 included in the first sub-peripheral circuit region SUB PERI1 and a second substrate 210 included in the second sub-peripheral circuit region SUB PERI2 may be formed to be in contact with each other. In the embodiment of FIG. 11, the thickness of a lowermost ILD region of the first sub-peripheral circuit region SUB PERI1 may also be different from the thickness of a lowermost ILD region of the second sub-peripheral circuit region SUB PERI2. According to an embodiment, in a stacked structure of a sub-peripheral circuit region included in a memory device, the first substrate 110 included in the first sub-peripheral circuit region SUB PERI1 and the second substrate 210 included in the second sub-peripheral circuit region SUB PERI2 may be sequentially stacked to be spaced apart from each other, as shown in FIG. 4. According to another embodiment, in a stacked structure of a sub-peripheral circuit region included in a memory device, the first substrate 110 included in the first sub-peripheral circuit region SUB PERI1 and the second substrate 210 included in the second sub-peripheral circuit region SUB PERI2 may be formed to be in contact with each other and may share a substrate, as shown in FIG. 11. Alternatively, according to another embodiment, the first substrate 110 included in the first sub-peripheral circuit region SUB PERI1 and the second substrate 210 included in the second sub-peripheral circuit region SUB PERI2 may also be formed on completely separate different chips.

The stacked structure of the first sub-peripheral circuit region SUB PERI1 and the second sub-peripheral circuit region SUB PERI2 is not limited thereto and may be variously changed within a range that satisfies a condition in which the thicknesses of lowermost ILD regions are different from each other, which is a characteristic, according to the present disclosure.

While the present disclosure has been particularly shown and described with reference to embodiments thereof, it is to be understood that various changes in form and details may be made therein without departing from the spirit and scope of the following claims.

1. A memory device, comprising:
a cell region in which a memory cell array is disposed; and
a peripheral circuit region at least partially vertically overlapping the cell region,
wherein the peripheral circuit region comprises:
a first sub-peripheral circuit region; and
a second sub-peripheral circuit region at least partially vertically overlapping the first sub-peripheral circuit region,
wherein a thickness of a first lowermost inter-layer dielectric (ILD) region of the first sub-peripheral circuit region is different from a thickness of a second lowermost ILD region of the second sub-peripheral circuit region.

2. The memory device of claim 1, wherein the thickness of the first lowermost ILD region of the first sub-peripheral circuit region comprises a first thickness between a first upper end portion of a first gate pattern of a first transistor disposed in the first sub-peripheral circuit region and a first metal pattern formed at a first lowermost end in a first insulator region in which the first transistor is formed, and
wherein the thickness of the second lowermost ILD region of the second sub-peripheral circuit region comprises a second thickness between a second upper end portion of a second gate pattern of a second transistor disposed in the second sub-peripheral circuit region and a second metal pattern formed at a second lowermost end in a second insulator region in which the second transistor is formed.

3. The memory device of claim 1, wherein an input/output circuit is disposed in the first sub-peripheral circuit region, and
wherein a pass transistor circuit is disposed in the second sub-peripheral circuit region.

4. The memory device of claim 3, wherein the thickness of the first lowermost ILD region of the first sub-peripheral circuit region is less than the thickness of the second lowermost ILD region of the second sub-peripheral circuit region.

5. The memory device of claim 1, wherein a high-speed transistor is disposed in the first sub-peripheral circuit region, and
wherein a high-voltage transistor is disposed in the second sub-peripheral circuit region.

6. The memory device of claim 5, wherein the thickness of the first lowermost ILD region of the first sub-peripheral circuit region is less than the thickness of the second lowermost ILD region of the second sub-peripheral circuit region.

7. A memory device, comprising:
a plurality of chips comprising a first chip, a second chip, and a third chip, the plurality of chips being sequentially stacked,
wherein a memory cell array is disposed in the first chip,
wherein a second sub-peripheral circuit region is disposed in the second chip,
wherein a first sub-peripheral circuit region is disposed in the third chip, and
wherein a thickness of a first lowermost inter-layer dielectric (ILD) region of the first sub-peripheral circuit region is different from a thickness of a second lowermost ILD region of the second sub-peripheral circuit region.

8. The memory device of claim 7, wherein an input/output circuit is disposed in the first sub-peripheral circuit region, and
wherein a pass transistor circuit and a row decoder are disposed in the second sub-peripheral circuit region.

9. The memory device of claim 8, wherein the thickness of the first lowermost ILD region of the first sub-peripheral circuit region comprises a first thickness between a first upper end portion of a first gate pattern of a first transistor disposed in the first sub-peripheral circuit region and a first metal pattern formed at a first lowermost end in a first insulator region in which the first transistor is formed, and
wherein the thickness of the second lowermost ILD region of the second sub-peripheral circuit region comprises a second thickness between a second upper end portion of a second gate pattern of a second transistor disposed in the second sub-peripheral circuit region and a second metal pattern formed at a second lowermost end in a second insulator region in which the second transistor is formed.

10. The memory device of claim 9, wherein the thickness of the first lowermost ILD region of the first sub-peripheral circuit region is less than the thickness of the second lowermost ILD region of the second sub-peripheral circuit region.

11. The memory device of claim 9, wherein a third thickness of the first gate pattern of the first transistor is different from a fourth thickness of the second gate pattern of the second transistor.

12. The memory device of claim 9, wherein a third thickness of the first metal pattern formed at the first lowermost end in the first insulator region in which the first transistor is formed is different from a fourth thickness of the second metal pattern formed at the second lowermost end in the second insulator region in which the second transistor is formed.

13. The memory device of claim 9, wherein a first depth of a shallow trench isolation (STI) region formed on a first side of the first transistor and a second side of the first transistor is different from a second depth of an STI region formed on a third side of the second transistor and a fourth side of the second transistor.

14. The memory device of claim 9, wherein a first material of a first contact coupled with a first active region of the first transistor is different from a second material of a second contact coupled with a second active region of the second transistor.

15. The memory device of claim 14, wherein the first material of the first contact comprises cobalt silicide (CoSiₓ), and
wherein the second material of the second contact comprises titanium silicide (TiSiₓ).

16. A memory device, comprising:
a cell region in which a memory cell array is disposed; and
a peripheral circuit region at least partially vertically overlapping the cell region,
wherein the peripheral circuit region comprises:
a first sub-peripheral circuit region; and
a second sub-peripheral circuit region at least partially vertically overlapping the first sub-peripheral circuit region,
wherein the first sub-peripheral circuit region comprises a first transistor region and a second transistor region,
wherein the second sub-peripheral circuit region comprises a third transistor region and a fourth transistor region, and
wherein thicknesses of first lowermost ILD regions of transistors disposed in the first transistor region and the second transistor region are different from thicknesses of second lowermost ILD regions of transistors disposed in the third transistor region and the fourth transistor region.

17. The memory device of claim 16, wherein a first thickness of a first gate oxide of a first transistor disposed in the first transistor region is different from a second thickness of a second gate oxide of a second transistor disposed in the second transistor region.

18. The memory device of claim 16, wherein a third thickness of a third gate oxide of a third transistor disposed in the third transistor region is different from a fourth thickness of a fourth gate oxide of a fourth transistor disposed in the fourth transistor region.

19. The memory device of claim 16, wherein a first transistor comprised by an input/output circuit is disposed in the second transistor region, and
wherein a second transistor comprised by a pass transistor circuit is disposed in the fourth transistor region.

20. The memory device of claim 19, wherein a first material of a first contact coupled with a first active region of a third transistor disposed in the second transistor region is different from a second material of a second contact coupled with a second active region of a fourth transistor disposed in the fourth transistor region.

21. (canceled)
